(19) United States
(12) Patent Application Publication
(10) Pub. No.: US 2025/0275157 A1
(43) Pub. Date: Aug. 28, 2025

(54) MIM CAPACITOR STRUCTURE WITH NON-CONFORMAL INSULATING LAYER AND FABRICATING METHOD OF THE SAME

(71) Applicant: UNITED MICROELECTRONICS CORP., Hsin-Chu City (TW)

(72) Inventors: Chih-Wei Kuo, Tainan City (TW); Chung-Yi Chiu, Tainan City (TW)

(73) Assignee: UNITED MICROELECTRONICS CORP., Hsin-Chu City (TW)

(21) Appl. No.: 18/602,002

(22) Filed: Mar. 11, 2024

(30) Foreign Application Priority Data
Feb. 22, 2024 (CN) 202410196439.X

(51) Int. Cl. H01L 21/764; H01L 23/522; H01L 23/532

(52) U.S. Cl. CPC H10D 1/042; H01L 21/764; H01L 23/5223; H01L 23/5329; H10D 1/716

(57) ABSTRACT

An MIM capacitor structure with a non-conformal insulating layer includes a substrate. A trench is disposed in the substrate. An MIM capacitor is disposed in the trench. An insulating layer non-conformally covers the trench, wherein the insulating layer contacts the MIM capacitor. The insulating layer has two overhangs formed at an opening of the trench. The overhangs seal the opening.

### BACKGROUND OF THE INVENTION

### 1. Field of the Invention

The present invention relates to a metal-insulator-metal (MIM) capacitor, and more particularly an MIM capacitor structure with a non-conformal insulating layer.

### 2. Description of the Prior Art

MIM capacitors are not only used to filter noise in radio frequency circuits, or as load components in digital circuits, it is also widely used in general integrated circuit and circuit board manufacturing processes. In recent years, with the development of semiconductor integrated circuit process technology, the minimum width of devices on semiconductor substrates has gradually become smaller; therefore the density of integrated circuits per unit area is increased.

However, during the formation of MIM capacitors, the grinding powder may remain on one material layer, causing another material layer disposed on the one material layer to peel off, thereby affecting the structure of the MIM capacitor.

### SUMMARY OF THE INVENTION

In view of this, the present invention provides an MIM capacitor structure with a non-conformal insulating layer to prevent grinding powder from remaining.

According to a preferred embodiment of the present invention, an MIM capacitor structure with a non-conformal insulating layer includes a substrate. A trench is disposed in the substrate. An MIM capacitor is disposed in the trench. An insulating layer non-conformally covers the trench, wherein the insulating layer contacts the MIM capacitor. The insulating layer has two overhangs formed at an opening of the trench, and the overhangs seal the opening.

According to another preferred embodiment of the present invention, a fabricating method of an MIM capacitor structure with a non-conformal insulating layer includes providing a substrate. Later, a trench is formed to be embedded in the substrate. Next, an MIM capacitor is formed to cover the trench. Finally, an insulating layer is non-conformally formed to cover the trench, and contact the MIM capacitor, wherein the insulating layer has two overhangs formed at an opening of the trench, and the overhangs seal the opening.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 depict a fabricating method of an MIM capacitor structure with a non-conformal insulating layer according to a preferred embodiment of the present invention, wherein:

FIG. 1 depicts a substrate with a trench therein;

FIG. 2 is a fabricating stage in continuous of FIG. 1;

FIG. 3 is a fabricating stage in continuous of FIG. 2;

FIG. 4 is a fabricating stage in continuous of FIG. 3; and

FIG. 5 is a fabricating stage in continuous of FIG. 4.

FIG. 6 to FIG. 8 depict a fabricating method of an MIM capacitor structure according to an examplary embodiemnt of the present invention, wherein:

FIG. 6 depicts a recess on a trench;

FIG. 7 is a fabricating stage in continuous of FIG. 6; and

FIG. 8 is a fabricating stage in continuous of FIG. 7.

### DETAILED DESCRIPTION

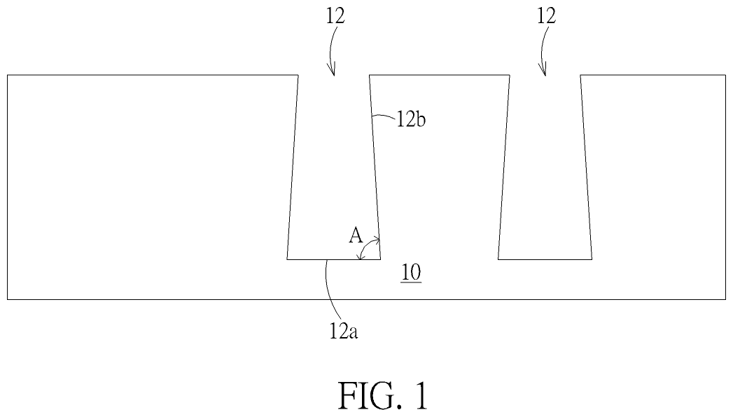

FIG. 1 to FIG. 5 depict a fabricating method of an MIM capacitor structure with a non-conformal insulating layer according to a preferred embodiment of the present invention.

As shown in FIG. 1, a substrate 10 is provided. Then, at least one trench 12 is formed to embed in the substrate 10. In FIG. 1, two trenches 12 are formed for an example, but the number of the trench 12 is not limited to two. Each of the trenches 12 includes a bottom 12a and a sidewall 12b. The bottom 12a and the sidewall 12b form an inner corner A. It is noteworthy that the angle of the inner corner A is between 85 and 90 degrees (excluding 90 degrees). In this way, the width of the trench 12 is reduced from the bottom 12a to the opening of the trench 12, which helps a non-conformal insulating layer to seal the opening of the trench 12 later.

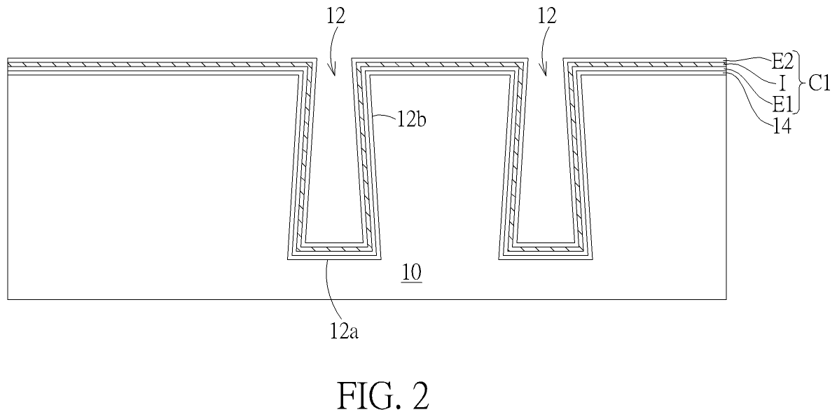

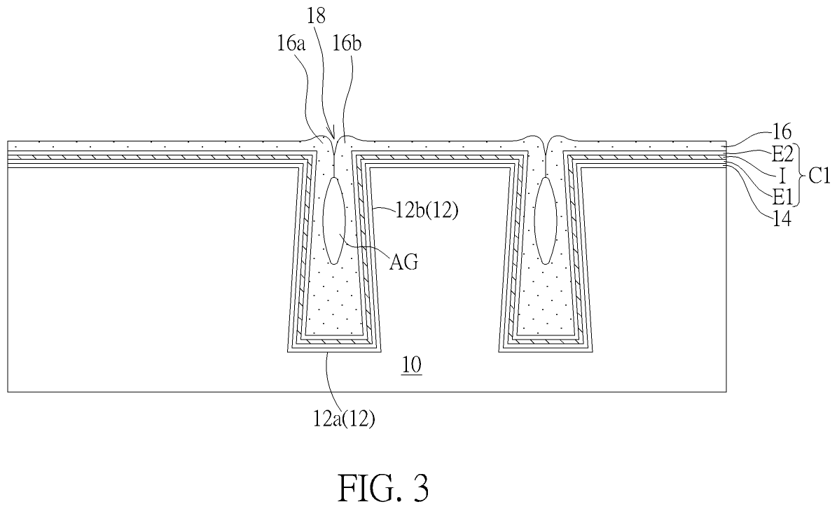

As shown in FIG. 2, a silicon oxide liner 14 is formed to conformally cover and contact the trench 12 and cover the top surface of the substrate 10. Later, a first electrode E1, a capacitor dielectric layer I and a second electrode E2 are formed in sequence to cover and contact the silicon oxide liner 14. The first electrode E1, the capacitor dielectric layer I and the second electrode E2 together form an MIM capacitor C1. In this embodiment, the first electrode E1, the capacitor dielectric layer I and the second electrode E2 continuously fill the two trenches 12. As shown in FIG. 3, a non-conformal insulating layer 16 is formed to cover the MIM capacitor C1. “Non-conformal” is because the thickness of the insulating layer 16 is inconsistent, the profile of the insulating layer 16 can't follow the profile of the trench 12. Specifically speaking, the thickness of the insulating layer 16 disposed at the inner corner A of the trench 12 (please refer to FIG. 1) is greater than the thickness of the insulating layer 16 disposed on the sidewall 12b of the trench 12. The thickness of the insulating layer 16 disposed at the opening of the trench 12 is greater than the thickness of the insulating layer 16 disposed on the sidewall 12b of the trench 12. In this way, two overhangs 16a/16b of the insulating layer 16 are formed at the opening of the trench 12, and the overhangs 16a/16b together seal the opening. An air gap AG is formed in the insulating layer 16. The insulating layer 16 may be formed by a chemical vapor deposition or a physical vapor deposition. In addition, a recess 18 is formed at the interface of the two overhangs 16a/16b. The insulating layer 16 includes silicon nitride, silicon oxynitride, silicon nitride carbide or silicon oxide.

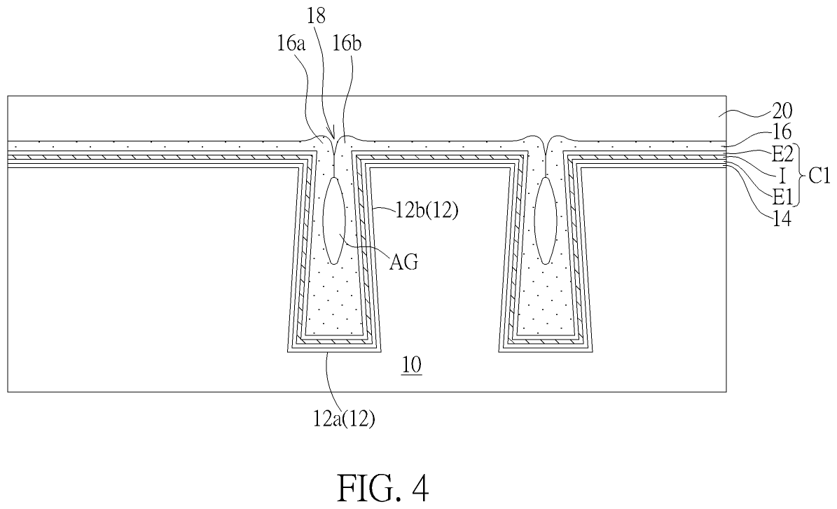

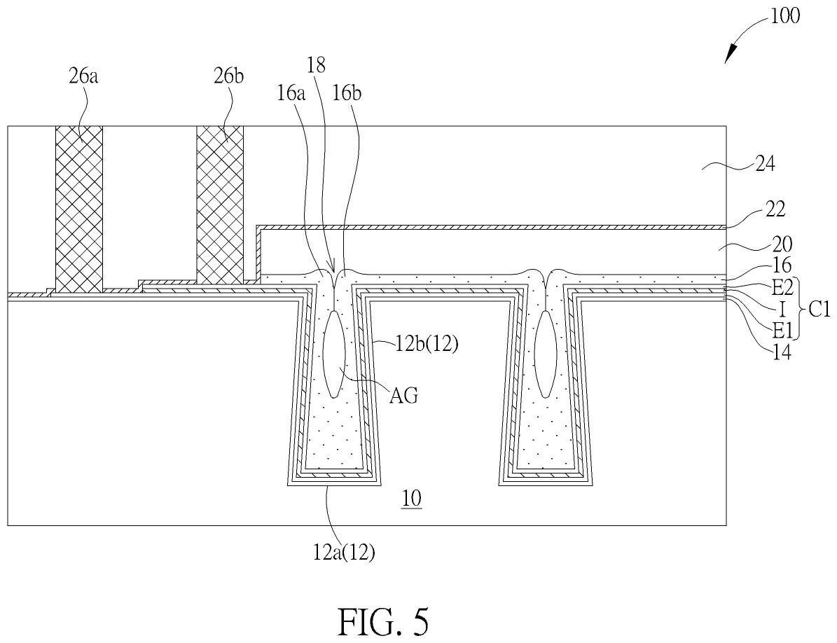

As shown in FIG. 4, a silicon oxide layer 20 is formed to cover the insulating layer 16, and the silicon oxide layer 20 fills the recess 18. As shown in FIG. 5, after planarizing the silicon oxide layer 20, part of the silicon oxide layer 20 and part of the insulating layer 16 on the top surface of the substrate 10 are removed. Later, part of the first electrode E1, part of the capacitor dielectric layer I and part of the second electrode E2 are removed. Next, a silicon nitride layer 22 is formed to cover the silicon oxide layer 20, the second electrode E2 and the first electrode E1. Subseqenctly, a dielectric layer 24 is formed to cover the silicon nitride layer 22 and the MIM capacitor C1. Then, a first contact plug 26a and a second contact plug 26b are formed to penetrate the dielectric layer 24 and the silicon nitride layer 22. The first contact plug 26a contacts the first electrode E1 and the second contact plug 26b contacts the second electrode E2. Now, an MIM capacitor structure 100 with a non-conformal insulating layer of the present invention is completed.

As shown in FIG. 5, an MIM capacitor structure 100 with a non-conformal insulating layer includes a substrate 10. The substrate 10 includes a silicon substrate, a germanium substrate, a gallium arsenide substrate, a silicon germanium substrate, an indium phosphide substrate, a gallium nitride substrate, a silicon carbide substrate or a silicon on insulator substrate. A trench 12 is disposed in the substrate 10. A silicon oxide liner 14 covers and contacts the trench 12. An MIM capacitor C1 is disposed in the trench 12 and contacts the silicon oxide liner 14. An insulating layer 16 non-conformally covers the trench 12, and the insulating layer 16 contacts the MIM capacitor C1. The insulating layer 16 forms two overhangs 16a/16b at an opening of the trench 12, and two overhangs 16a/16b seal the opening. The insulating layer 16 includes silicon nitride, silicon oxynitride, silicon nitride carbide or silicon oxide.

The MIM capacitor C1 includes a first electrode E1, a capacitor dielectric layer I and a second electrode E2. An air gap AG is disposed in the insulating layer 16 and located within the trench 12. The first electrode E1 and the second electrode E2 respectively include tantalum nitride, titanium nitride, tantalum, titanium, aluminum or poly-crystalline silicon. The capacitor dielectric layer I includes aluminum oxide, zirconium oxide, barium strontium titanate (BST), lead zirconate titanate (PZT), zirconium silicate (ZrSiO₄), hafnium silicon oxide (HfSiO₂), hafnium silicon oxynitride (HfSiON), tantalum oxide or a combination of the above materials.

Moreover, the trench 12 includes a bottom 12a and a sidewall 12b. The bottom 12a and the sidewall 12b form an inner angle A (please refer to FIG. 1). The inner angle A faces the MIM capacitor C1, and the angle of the inner angle A is between 85 and 90 degrees. The thickness of the insulating layer 16 disposed at the inner corner A is greater than the thickness of the insulating layer 16 disposed on the sidewall 12b of the trench 12, and the thickness of the insulating layer 16 disposed at the opening of the trench 12 is greater than the thickness of the insulating layer 16 disposed on the sidewall 12b of the trench 12. The insulating layer 16 located at the opening of the trench 12 is defined as overhangs 16a/16b. In addition, the silicon oxide layer 20 covers and contacts the insulating layer 16. A silicon nitride layer 22 covers the silicon oxide layer 20, the second electrode E2 and the first electrode E1.

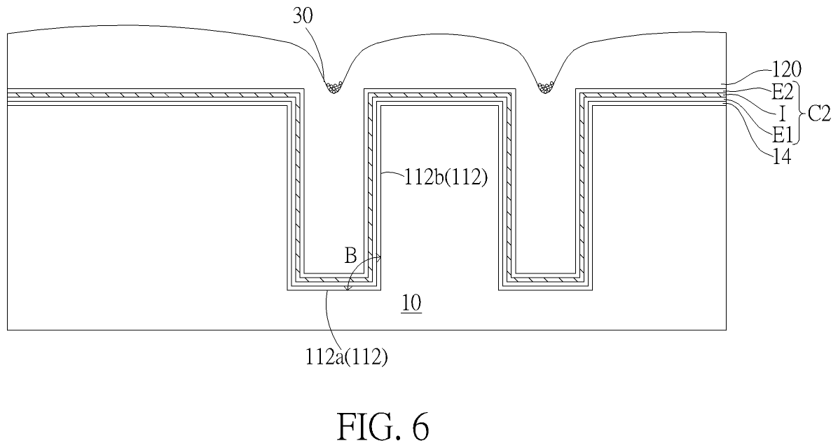

FIG. 6 to FIG. 8 depict a fabricating method of an MIM capacitor structure according to an examplary embodiemnt of the present invention, wherein like reference numerals are used to refer to like elements throughout.

As shown in FIG. 6, a substrate 10 is provided. Then, at least one trench 112 is formed in the substrate 10. The trench 112 includes a bottom 112a and a sidewall 112b. The bottom 112a and the sidewall 112b form an inner angle B. The inner angle is 90 degrees or greater than 90 degrees. In this way, the width of the bottom 112a of the trench 112 may be equal to or smaller than the width of the opening of the trench 112. Therefore, air gaps are less likely to form in trench 112. Thereafter, a silicon oxide liner 14, a first electrode E1, a capacitor dielectric layer I and a second electrode E2 are sequentially formed to cover the trench 112 and the top surface of the substrate 10. The first electrode E1, the capacitor dielectric layer I and the second electrode E2 together form an MIM capacitor C2. Later, a silicon oxide layer 120 is formed to cover the second electrode E2 and fill in the trench 112. The silicon oxide layer 120, the first electrode E1, the capacitor dielectric layer I and the second electrode E2 together fill up the trench 112. The silicon oxide layer 120 needs to fill the space in the trench 112 where there is no the first electrode E1, the capacitor dielectric layer I or the second electrode E2 filling in, therefore the silicon oxide layer 120 will form a recess 30 on the opening of the trench 112. The lowest point of the recess 30 is sandwiched between the second electrode E2 disposed on the two sidewalls 112b of the trench 112. The silicon oxide layer 120 may be formed by a chemical vapor deposition, a physical vapor deposition, or an atomic layer deposition. In this embodiment, the silicon oxide layer 120 is preferably formed by an atomic layer deposition.

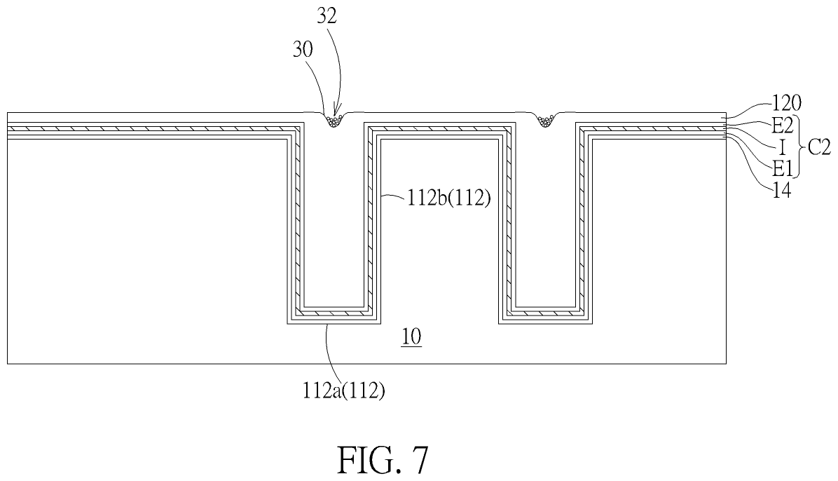

As shown in FIG. 7, the silicon oxide layer 120 is planarized. The method of planarizing the silicon oxide layer 120 is preferably performed by a chemical mechanical polishing process. Since slurry is used during the chemical mechanical polishing process, the grinding powder 32 in the slurry may stuck in the recess 30. Because the lowest point of the recess 30 is sandwiched between the second electrode E2 located on the two sidewalls 112b of the trench 112, the recess 30 of the silicon oxide layer 120 cannot be completely removed, otherwise the second electrode E2 will be ground. In order to protect the second electrode E2 during the chemical mechanical polishing process, a certain thickness of the silicon oxide layer 120 needs to be maitained on the second electrode E2. As a result, after the chemical mechanical polishing process is completed, part of the recess 30 still remains, and the grinding powder 32 remains in the recess 30.

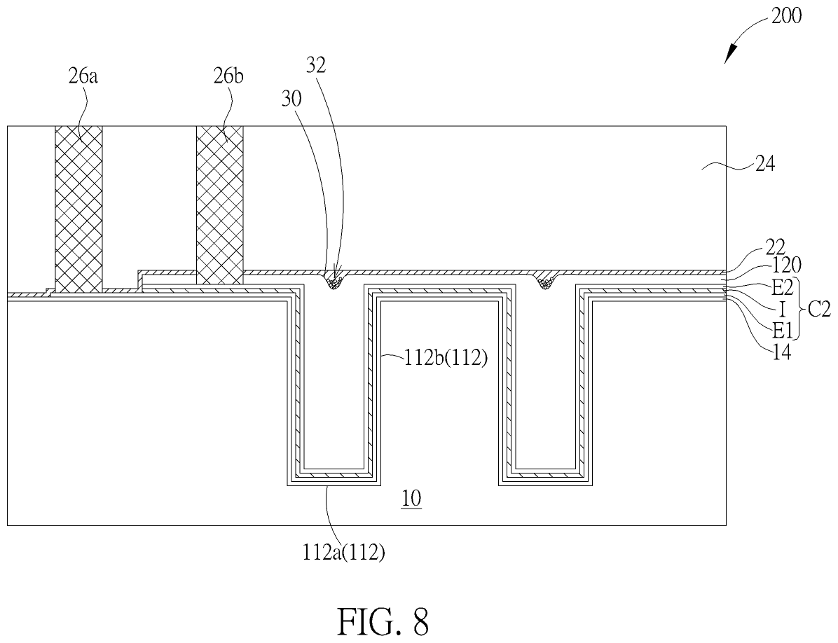

As shown in FIG. 8, part of the silicon oxide layer 120 on the top surface of the substrate 10 is removed. The subsequent processes are the same as those in FIG. 5. For example, part of the silicon oxide layer 120, part of the first electrode E1, part of the capacitor dielectric layer I and part of the second electrode E2 are removed. Then, a silicon nitride layer 22 is formed to cover the silicon oxide layer 120, the recess 30, the second electrode E2 and the first electrode E1. Later, the dielectric layer 24, the first contact plug 26a and the second contact plug 26b are formed. Now, an MIM capacitor structure 200 of the present invention is completed.

In the MIM capacitor structure 200, there is grinding powder 32 remaining between the silicon nitride layer 22 and the silicon oxide layer 120, therefore the silicon nitride layer 22 can not attach to the silicon oxide layer 120 completely. In this way, the silicon nitride layer 22 is easily delaminated, damaging the MIM capacitor structure 200. Regarding the MIM capacitor structure 100 with a non-conformal insulating layer, the opening of the trench 12 is seal up by the non-conformal insulating layer 16, and the thickness of the insulating layer 16 is smaller than that of the silicon oxide layer 120. Therefore, the depth of the recess 18 of the insulating layer 16 is smaller than the depth of the recess 30 of the silicon oxide layer 120. That is, the recess 18 is flatter than the recess 30. By this process, when the silicon oxide layer 20 is formed on the insulating layer 18 thereafter, the silicon oxide layer 20 can fill up the recess 18. Later, the silicon oxide layer 20 is planarized. Comparing to the examplary embodiment, the process in the preferred embodiment does not have the recess on the silicon oxide layer 20, and without grinding powder 32 remained. Therefore, in the MIM capacitor structure 100 with a non-conformal insulating layer, the silicon nitride layer 22 can completely attach to the silicon oxide layer 20.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A metal-insulator-metal (MIM) capacitor structure with a non-conformal insulating layer, comprising:
a substrate;
a trench disposed in the substrate;
an MIM capacitor disposed in the trench; and
an insulating layer non-conformally covering the trench, wherein the insulating layer contacts the MIM capacitor, the insulating layer has two overhangs formed at an opening of the trench, and the overhangs seal the opening.

2. The MIM capacitor structure with a non-conformal insulating layer of claim 1, further comprising a silicon oxide layer covering and contacting the insulating layer.

3. The MIM capacitor structure with a non-conformal insulating layer of claim 1, wherein the trench comprises a bottom and a sidewall, the bottom and the sidewall form an inner corner, the inner corner faces the MIM capacitor, and an angle of the inner corner is between 85 and 90 degrees.

4. The MIM capacitor structure with a non-conformal insulating layer of claim 3, wherein a thickness of the insulating layer at the inner corner is greater than a thickness of the insulating layer on the sidewall of the trench.

5. The MIM capacitor structure with a non-conformal insulating layer of claim 1, wherein a thickness of the insulating layer disposed at the opening is greater than a thickness of the insulating layer disposed at a sidewall of the trench.

6. The MIM capacitor structure with a non-conformal insulating layer of claim 1, further comprising a silicon oxide liner covering and contacting the trench, and the MIM capacitor contacting the silicon oxide liner.

7. The MIM capacitor structure with a non-conformal insulating layer of claim 1, wherein an air gap is disposed in the insulating layer.

8. The MIM capacitor structure with a non-conformal insulating layer of claim 1, wherein the insulating layer comprises silicon nitride, silicon oxynitride, silicon carbon nitride or silicon oxide.

9. A fabricating method of a metal-insulator-metal (MIM) capacitor structure with a non-conformal insulating layer, comprising:
providing a substrate;
forming a trench embedded in the substrate;
forming an MIM capacitor covering the trench; and
non-conformally forming an insulating layer covering the trench, and contacting the MIM capacitor, wherein the insulating layer has two overhangs formed at an opening of the trench, and the overhangs seal the opening.

10. The fabricating method of an MIM capacitor structure with a non-conformal insulating layer of claim 9, further comprising:
forming a silicon oxide layer covering and contacting the insulating layer; and
planarizing the silicon oxide layer.

11. The fabricating method of an MIM capacitor structure with a non-conformal insulating layer of claim 9, wherein the trench comprises a bottom and a sidewall, the bottom and the sidewall form an inner corner, the inner corner faces the MIM capacitor, and an angle of the inner corner is between 85 and 90 degrees.

12. The fabricating method of an MIM capacitor structure with a non-conformal insulating layer of claim 11, wherein a thickness of the insulating layer at the inner corner is greater than a thickness of the insulating layer on the sidewall of the trench.

13. The fabricating method of an MIM capacitor structure with a non-conformal insulating layer of claim 9, wherein a thickness of the insulating layer disposed at the opening is greater than a thickness of the insulating layer disposed at a sidewall of the trench.

14. The fabricating method of an MIM capacitor structure with a non-conformal insulating layer of claim 9, wherein an air gap is disposed in the insulating layer.

15. The fabricating method of an MIM capacitor structure with a non-conformal insulating layer of claim 9, wherein the insulating layer comprises silicon nitride, silicon oxynitride, silicon carbon nitride or silicon oxide.
